(19) United States
(12) Patent Application Publication
(10) Pub. No.: US 2008/0272780 A1
(43) Pub. Date: Nov. 6, 2008

(54) Method for Accounting for Shifted Metabolic Volumes in Spectroscopic Imaging

(75) Inventors: Michael R. Thompson, Cleveland Heights, OH (US); Derrick P. Green, Mayfield Village, OH (US)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS N.V., Eindhoven (NL)

(21) Appl. No.: 12/067,362

(22) PCT Filed: Aug. 18, 2006
(86) PCT No.: PCT/IB2006/052869

§ 371 Date: Mar. 19, 2008

Related U.S. Application Data
(60) Provisional application No. 60/718,822, filed on Sep. 20, 2005.

(51) Int. Cl. G01R 33/485

(52) U.S. Cl. 324/309

(57) ABSTRACT

In a magnetic resonance method, a localizing magnetic field gradient (G_{L}) is determined suitable for acquiring a first resonant species magnetic resonance localized to a first sampling region (Rₘ₁). A second sampling region (Rₘ₂) defined by the localizing magnetic field gradient for a second resonant species magnetic resonance is determined. The second sampling region is spatially shifted from the first sampling region due to different gyromagnetic ratios of the first and second resonant species magnetic resonances. At least the second sampling region is displayed together with an image (62) of a subject disposed in the main magnetic field.

The following relates to the magnetic resonance arts. It finds particular application in magnetic resonance spectroscopy, and will be described with particular reference thereto. However, it also finds application in magnetic resonance imaging, multi-nuclear magnetic resonance spectroscopy, in multi-nuclear magnetic resonance imaging, and so forth.

Magnetic resonance spectroscopy can provide chemical information about a region of interest based on the chemical shift of the magnetic resonance. For example, the magnetic resonance frequency of a proton shifts depending upon the chemical environment in which the proton resides. Some common metabolite species used for proton-based magnetic resonance spectroscopy of the brain include N-acetylaspartate (NAA), creatine, and choline. Other metabolite species, such as lactate, myoinositol, glutamate, glutamine, alanine, and so forth, may be of interest for spectroscopy of the brain or other organs or anatomical features. In some approaches, a ratio of the levels of two metabolite species having a predetermined clinical significance, such as a choline:creatine ratio, is measured. The magnitude of the chemical shift increases linearly with main (B₀) magnetic field strength. Thus, magnetic resonance spectroscopy is advantageously performed in high-field magnetic resonance scanners, for example operating at 3 Tesla or higher, although lower-field scanners can be used.

Magnetic field gradients are applied during the magnetic resonance data acquisition to localize the spectroscopic signals to a volume, slice, or other spatial region. If the magnetic resonance signal is spatially encoded using applied magnetic field gradients, then a magnetic resonance spectroscopic map or image can be generated. The magnetic resonance signal strength of typical metabolites of interest, such as NAA, creatine, and choline, are substantially lower than the magnetic resonance signal strengths of the dominant water and fat metabolites. Accordingly, fat and/or water saturation or other signal suppression techniques are typically applied to suppress the fat and/or water signals when performing magnetic resonance spectroscopy. The localized region defined by the magnetic field gradients is advantageously made large to maximize the magnetic resonance signal strength of the metabolites of interest. This localized region should however be contained within the tumor or other feature or region of interest that is being analyzed, mapped, or imaged.

Typically, the localizing magnetic field gradients for use in magnetic resonance spectroscopy are set up based on the main magnetic resonance frequency of the magnetic resonance scanner (which may be, for example, the resonance frequency of protons in water). A problem arises, however, in that the chemical shift that is exploited in magnetic resonance spectroscopy also produces a corresponding spatial shift in the localized region defined by the localizing magnetic field gradients. That is, for a given localizing magnetic field gradient or set of gradients, different metabolites are sampled in different spatial regions.

Thus, the spatial region set up based on the scanner resonance frequency does not precisely correspond to the spatial region in which the metabolite is sampled. These spatial errors increase with increasing main magnetic field strength, and thus are more problematic for the high-field magnetic resonance scanners preferred for spectroscopic applications. In the case of a small tumor, or a large region of interest (such as is preferred to maximize the magnetic resonance signal), the spatial error caused by the chemical shift can result in the sampled region for the metabolite of interest extending outside of the tumor or other feature of interest.

When two metabolite magnetic resonances are ratioed, the magnetic resonance of each metabolite of the ratio is acquired from a different sampled volume due to the differing chemical shifts of the two metabolites. If one or both of these spatially shifted regions extends outside of the tumor or other region of interest, then the measured metabolite magnetic resonance ratio will not correspond to the metabolite magnetic resonance ratio of tissue of the tumor.

Problems can arise even if the spatially localized region for the metabolite of interest is contained within the tumor or other feature of interest. If, for example, the spatially localizing magnetic field gradients cause the region of localization for fat magnetic resonance to extend outside the tumor and into a fatty anatomical region, the result can be a large increase in the fat magnetic resonance signal, which can interfere with the metabolite magnetic resonance signal of interest, even when fat suppression is applied in the magnetic resonance spectroscopy sequence.

The spatial error caused by the chemical shift can be reduced by increasing the localizing magnetic field gradient strength. However, SAR considerations can limit the magnetic field gradient strength, especially in the case of a high-field magnetic resonance scanner. Moreover, increasing the magnetic field gradient strength reduces the size of the sampled spatial region, which reduces the magnetic resonance signal of the metabolite or metabolites of interest.

The following contemplates improved apparatuses and methods that overcome the aforementioned limitations and others.

According to one aspect, a magnetic resonance method is disclosed. A localizing magnetic field gradient is determined suitable for acquiring a first metabolite magnetic resonance localized to a first sampling region. A second sampling region defined by the localizing magnetic field gradient for a second metabolite magnetic resonance is determined. The second sampling region is spatially shifted from the first sampling region due to different chemical shifts of the first and second metabolite magnetic resonances. At least the second sampling region is displayed together with an image of a subject disposed in the main magnetic field.

According to another aspect, a magnetic resonance apparatus is disclosed. A magnetic resonance scanner acquires magnetic resonance. The scanner includes one or more magnetic field gradient coils for superimposing one or more localizing magnetic field gradients on a main magnetic field. A processor is configured to perform the magnetic resonance method of the preceding paragraph.

According to another aspect, a magnetic resonance method is disclosed. A localizing magnetic field gradient is determined suitable for acquiring a first resonant species magnetic resonance localized to a first sampling region. A second sampling region defined by the localizing magnetic field gradient for a second resonant species magnetic resonance is determined. The second sampling region is spatially shifted from the first sampling region due to different gyromagnetic ratios of the first and second resonant species magnetic resonances. At least the second sampling region is displayed together with an image of a subject disposed in the main magnetic field.

One advantage resides in providing more robust magnetic resonance spectroscopy of multiple metabolite species.

Another advantage resides in more accurate spectroscopic characterization of tumors and other regions of interest.

Another advantage resides in improved workflow for spectroscopic characterization of tumors and other regions of interest.

Another advantage resides in reduced magnetic resonance interference from fatty or high-water tissues neighboring a tumor or other region of interest.

Numerous additional advantages and benefits will become apparent to those of ordinary skill in the art upon reading the following detailed description of the preferred embodiments.

The invention may take form in various components and arrangements of components, and in various process operations and arrangements of process operations. The drawings are only for the purpose of illustrating preferred embodiments and are not to be construed as limiting the invention.

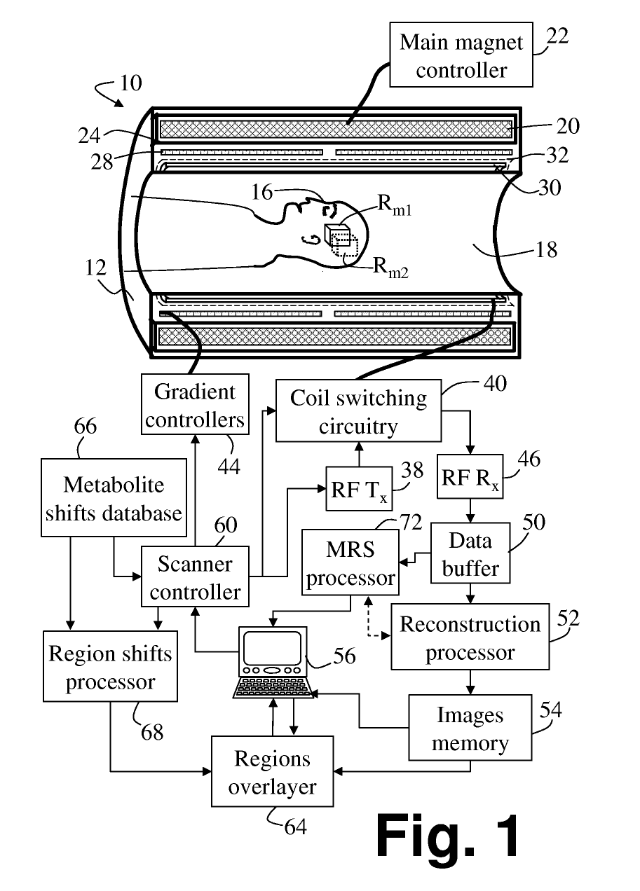

FIG. 1 diagrammatically shows an example magnetic resonance system for performing magnetic resonance spectroscopy, including optional imaging.

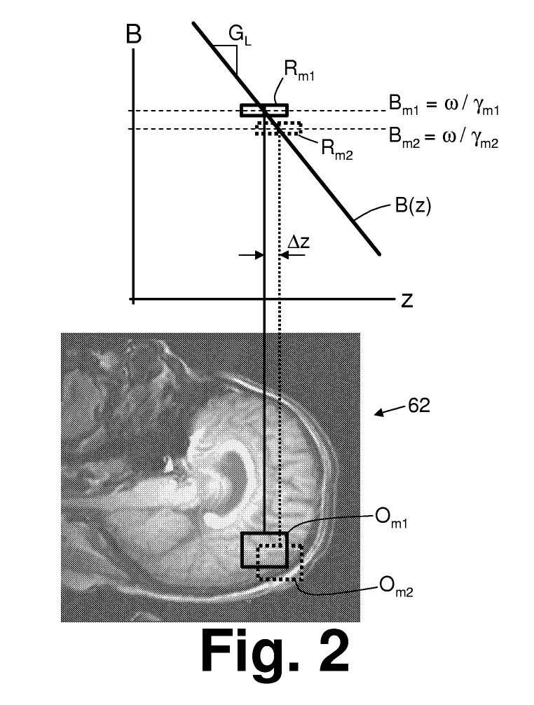

FIG. 2 diagrammatically shows graphical visualization of the sampling region of two metabolite species. The top portion of FIG. 2 diagrammatically shows determination of the z-component of the sampling regions.

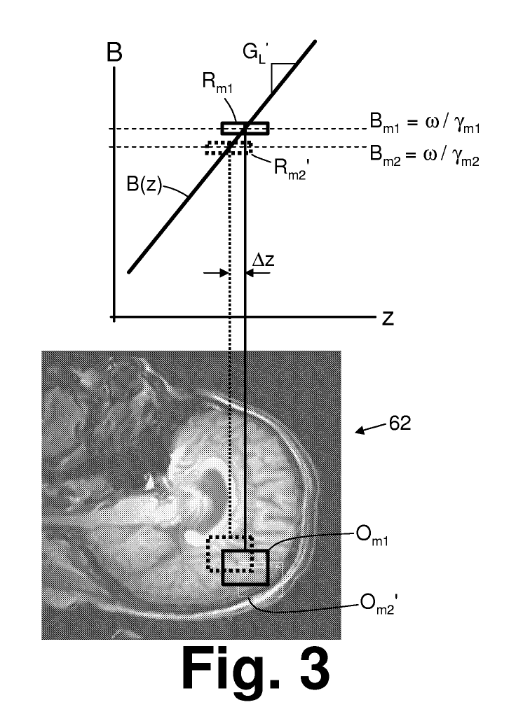

FIG. 3 diagrammatically shows graphical visualization of the sampling region of two metabolite species. FIG. 3 is similar to FIG. 2 except that the direction of the localizing magnetic field gradient is reversed.

With reference to FIG. 1, a magnetic resonance scanner 10 is configured to perform magnetic resonance spectroscopy optionally including metabolite analysis, multiple-metabolite species imaging, multi-nuclear imaging, or so forth. The scanner 10 optionally is also configured to perform magnetic resonance imaging. The illustrated example scanner 10 includes a scanner housing 12 in which a patient or other subject 16 is at least partially disposed. A bore liner 18 of the scanner housing 12 optionally lines a cylindrical bore or opening of the scanner housing 12 inside of which the subject 16 is disposed. A main magnet 20 disposed in the scanner housing 12 is controlled by a main magnet controller 22 to generate a B₀ main magnetic field at least in the region of interest 14 including at least a portion of the subject 16. Typically, the main magnet 20 is a persistent superconducting magnet surrounded by cryoshrouding 24, although a resistive magnet can also be used. The main magnet 20 generates a main B₀ magnetic field of typically about 3 Tesla or higher. In some embodiments, the main B₀ magnetic field is about 7 Tesla.

Magnetic field gradient coils 28 are arranged in or on the housing 12 to superimpose selected magnetic field gradients on the main B₀ magnetic field at least in a region of interest. Typically, the magnetic field gradient coils include coils for producing three orthogonal magnetic field gradients, such as an x-gradient, y-gradient, and z-gradient. A whole-body radio frequency coil 30 is disposed in the housing 12, as shown, or in the bore of the scanner 10, to inject B, radio frequency excitation pulses and to measure magnetic resonance signals. The radio frequency coil 30 is generally cylindrical and coaxially aligned with the bore of the scanner 10, and includes a surrounding coaxial, generally cylindrical radio frequency shield 32. Additionally or alternatively, local radio frequency coils such as head coils, surface coils, or so forth can be used for the excitation phase, readout phase, or both phases of the magnetic resonance data acquisition sequence.

During optional magnetic resonance imaging, a radio frequency power source 38 is coupled to the radio frequency coil 30, or to another radio frequency coil or coils array, through radio frequency switching circuitry 40 to inject radio frequency excitation pulses so as to generate magnetic resonance signals in a region of interest of the subject 16. A magnetic field gradients controller 44 operates the magnetic field gradient coils 28 to spatially localize or encode generated magnetic resonances. During the magnetic resonance readout phase, the switching circuitry 40 connects a radio frequency receiver 46 to the radio frequency coil 30, or to another radio frequency coil or coils array, to acquire magnetic resonance signals from the region of interest of the subject 16. If different excitation and receive coils are used, then the switching circuitry 40 is optionally omitted.

Acquired magnetic resonance signals are stored in a data buffer 50, and are processed by a reconstruction processor 52 to produce a reconstructed image of the region of interest that is stored in an images memory 54. The reconstruction processor 52 employs a reconstruction algorithm that suitably decodes the spatially encoded magnetic resonances. For example, if Cartesian encoding is employed, a two or three dimensional fast Fourier transform (FFT) reconstruction algorithm may be suitable. The reconstructed image is displayed on a user interface 56 or on another high resolution display device, is printed, communicated over the Internet or a local area network, stored on a non-volatile storage medium, or is otherwise used. In the example embodiment illustrated in FIG. 1, the user interface 56 also interfaces a radiologist or other user with a scanner controller 60 to control the magnetic resonance scanner 10. In other embodiments, a separate scanner control interface may be provided.

In magnetic resonance spectroscopy, one or more magnetic resonance images are typically first acquired, for example using the ¹H proton resonance, to provide an image of the subject 16 in the main magnetic field for identifying a feature of interest such as a tumor. Alternatively, another imaging modality can be used to acquire the image of the subject 16 in the main magnetic field for identifying the tumor or other feature of interest. For example, the imaging modality can be ultrasound, positron emission tomography (PET), single photon emission computed tomography (SPECT), transmission computed tomography (CT), or so forth.

With continuing reference to FIG. 1 and with further reference to FIG. 2, the user employs the user interface 56 to select a first sampling region Rₘ₁ for sampling a first metabolite, such as N-acetylaspartate (NAA), creatine, choline, or so forth. In some embodiments, the user interface 56 is a graphical user interface that provides an image display 62 of the image of the subject 16, and the user marks the first sampling region graphically on the image display 62, for example by using a rubber-band box that is user-manipulated via a mouse or other input device. A regions overlayer 64 displays the first sampling region Rₘ₁ together with the image of the subject, for example by generating and displaying an overlay Oₘ₁ of the first sampling region Rₘ₁ on the image display 62. The regions overlayer 64 can be a separate component as shown, or can be integral with the user interface 56, such as software executing on the user interface 56.

In some contemplated embodiments, the user clicks inside of a tumor or other substantially homogeneous feature in the image display 62. Region-fitting software of the user interface 56 or regions overlayer 64 determines boundaries of the first sampling region Rₘ₁ that fit inside of the tumor or other substantially homogeneous feature containing the selected (clicked) location, and the determined boundaries are displayed as the first region overlay Oₘ₁. In some contemplated embodiments, region-identifying software implements a suitable algorithm that identifies the tumor or other region of interest in the image display 62 based on identifying characteristics such as density, texture, shape, or so forth.

The scanner controller 60 determines a localizing magnetic field gradient G_{L} suitable for acquiring first metabolite magnetic resonance localized to the first sampling region Rₘ₁ selected by the user. For example, to acquire first metabolite magnetic resonance localized to an axial slice, the localizing magnetic field gradient G_{L} is suitably selected as a magnetic field gradient in the z-direction, with a strength corresponding to the extent of desired localization. A higher magnetic field gradient localizes the first metabolite magnetic resonance to a relatively thinner slice. To acquire first metabolite magnetic resonance localized to a square or rectangular region having sides aligned with the x-, y-, and z-directions, the localizing magnetic field gradient G_{L} suitably includes magnetic field gradient components in the x-, y-, and z-directions, with the gradient strength in each direction corresponding to the extent of desired spatial localization in that direction. Regions of interest having other shapes or orientations can also be selected, and suitable magnetic field gradients determined.

In determining the localizing magnetic field gradient G_{L}, the scanner controller 60 takes into account the precise gyromagnetic ratio γₘ₁ of the first metabolite. Each nuclear species in isolation has a characteristic gyromagnetic ratio. For example, the ¹H magnetic resonance has a gyromagnetic ratio of about 42.58 MHz/T. The magnetic resonance frequency is the product of the gyromagnetic ratio times the magnetic field, that is, γB where B is the main B₀ magnetic field modified by any applied magnetic field gradient. The gyromagnetic ratio of a metabolite, that is, a specific chemical environment in which a nuclear species resides, typically exhibits a chemical shift in its gyromagnetic ratio. For example, the gyromagnetic ratio of the protons in NAA, creatine, choline, or other metabolites of hydrogen are chemically shifted from one another by small amounts, typically measured in parts-per-million (ppm).

A metabolite shifts database 66 stores the chemical shift or gyromagnetic ratio of each metabolite of interest. For example, the metabolite shifts database 66 may store chemical shifts for NAA, creatine, choline, fat, and other metabolites of interest, relative to a suitable reference such as the gyromagnetic ratio of protons in water. The metabolite shifts database 66 can store this information in other forms, such as storing the absolute observed gyromagnetic ratio for each metabolite. Typically, the radio frequency transmitter 38 operates at a selected radio frequency ω. For the first metabolite having gyromagnetic ratio γₘ₁, the sampling region Rₘ₁ is located where the magnetic field Bₘ₁, defined by the main B₀ magnetic field modified by the superimposed localizing magnetic field gradient G_{L}, equals ω/γₘ₁.

In addition to the first metabolite, at least one other metabolite is considered. In some embodiments, the at least one other metabolite includes a second metabolite of interest such as NAA, creatine, choline, or so forth, that is different from the first metabolite. Comparison of first and second metabolites, for example by ratioing the magnetic resonance of the two metabolites, can provide clinically significant information. In some embodiments, the at least one other metabolite includes a high-concentration metabolite such as fat or water, which is not itself of interest but which could interfere with the measurement of the metabolite or metabolites of interest.

A region shifts processor 68 determines the second sampling region Rₘ₂ for a second metabolite. The second sampling region Rₘ₂ is defined by the localizing magnetic field gradient G_{L} and corresponds to the region from which second metabolite magnetic resonance is acquired when using the localizing magnetic field gradient G_{L}. The second sampling region Rₘ₂ is spatially shifted from the first sampling region Rₘ₁ due to the different chemical shifts of the first and second metabolite magnetic resonances. Accordingly, the region shifts processor 68 accesses the metabolite shifts database 66 to determine the gyromagnetic ratio γₘ₂ for the second metabolite. The sampling region Rₘ₂ is located where the magnetic field Bₘ₂ defined by the main B₀ magnetic field modified by the superimposed localizing magnetic field gradient G_{L}, equals ω/γₘ₂.

In the example shown in FIG. 2, γₘ₁<γₘ₂ and so Bₘ₁>Bₘ₂. In the example decreasing localizing magnetic field gradient G_{L} shown in FIG. 2, the second sampling region Rₘ₂ is shifted to a larger z value respective to the first sampling region Rₘ₁. On the other hand, if γₘ₁>γₘ₂ then the second sampling region would be shifted to smaller z value respective to the first sampling region.

There can be more than two metabolites of interest or concern. The region shifts processor 68 suitably repeats the region determination process for optional third or more metabolites each having different gyromagnetic ratios to determine the shifted region for the third or more metabolites.

The regions overlayer 64 displays the determined second sampling region Rₘ₂ together with the image of the subject, for example by generating and displaying second region overlay Oₘ₂ corresponding to the second sampling region Rₘ₂ on the image display 62. The user can then visually determine whether the second sampling region Rₘ₂ is acceptable. In the example shown in FIG. 2, if the second metabolite is fat then the user will likely decide that the second sampling region Rₘ₂ is not satisfactory, because it overlays the outer brain membrane which contains a substantial amount of fatty tissue. This excessive amount of fat in the second sampling region Rₘ₂ could produce a strong fat magnetic resonance that overwhelms the first metabolite magnetic resonance, even if fat suppression is used. Similarly, if the second metabolite is a second metabolite of interest that is to be compared with the first metabolite, the user likely will decide that the second sampling region Rₘ₂ is not satisfactory, because the first and second sampling regions Rₘ₁, Rₘ₂ are dissimilar.

If the user rejects the second sampling region Rₘ₂, various remedial actions can be taken. In one option, the user chooses to relocate the first region of interest Rₘ₁, which will also relocate the second sampling region Rₘ₂.

Another remediation option is described with reference to FIG. 2 and with further reference to FIG. 3. Given the situation shown in FIG. 2 in which the second sampling region Rₘ₂ is shifted into an undesirable anatomical region, the user can select to have an alternative, different localizing magnetic field gradient G_{L}′ determined which is also suitable for acquiring first metabolite magnetic resonance localized to the first sampling region Rₘ₁. For the example of FIG. 2, the different localizing magnetic field gradient G_{L}′ is suitably obtained by reversing the direction of the localizing magnetic field gradient G_{L} to obtain the different localizing magnetic field gradient G_{L}′. The shift shown in FIG. 3 is suitably obtained by reversing the x-, y-, and z-components of the magnetic field gradient G_{L}. In another alternative, only one or two components, such as only the z-component, of the localizing magnetic field gradient G_{L} can be reversed. The region shifts processor 68 determines a different second sampling region Rₘ₂′ defined by the different localizing magnetic field gradient G_{L}′ for the second metabolite magnetic resonance. The regions overlayer 64 superimposes overlay Oₘ₂′ corresponding to the different second sampling region Rₘ₂′ on the image display 62, as shown in FIG. 3. By reversing the magnetic field gradient or one or more components thereof, the shift of the second sampling region Rₘ₂₁ is reversed to another side of the first sampling region Rₘ₁, which is advantageously selected to be away from the fatty outer brain membrane.

Once the user accepts the second sampling region Rₘ₂ or Rₘ₂′ (and optionally accepts third or additional sampling regions for third or additional metabolites of interest or concern), the magnetic resonance scanner 10 acquires a magnetic resonance signal including first metabolite magnetic resonance localized to the first sampling region Rₘ₁ by the localizing magnetic field gradient G_{L} or G_{L}′, and stores the acquired magnetic resonance in a data buffer 50. The radio frequency excitation that produces the first metabolite magnetic resonance also produces second metabolite magnet resonance localized to the second sampling region Rₘ₂ or Rₘ₂′ by the localizing magnetic field gradient G_{L} or G_{L}′, respectively. Optionally, the second metabolite is fat or another metabolite whose magnetic resonance is suppressed using suitable suppression features of the magnetic resonance sequence. In such cases, the second metabolite magnetic resonance is not of interest. Optionally, the second metabolite is a second metabolite of interest. A magnetic resonance spectroscopy processor 72 processes the stored magnetic resonance signal and extracts the first magnetic resonance which is of interest, and optionally extracts the second magnetic resonance if it is also of interest. Extraction of specific metabolite magnetic resonance signals is suitably done by spectral filtering, for example using Fast Fourier Transform (FFT) processing.

Optionally, the magnetic resonance spectroscopy is spatially encoded to generate a map or image of the first (and optionally second) metabolite magnetic resonance. Optionally, the magnetic resonance spectroscopy processor 72 communicates with the reconstruction processor 52 to decode the spatial encoding so as to reconstruct the map or image. Alternatively, the magnetic resonance spectroscopy processor 72 can include algorithms for performing the spatial decoding. Optionally, the magnetic resonance spectroscopy processor 72 ratios the magnetic resonance signals of the first and second metabolites. The processed magnetic resonance spectroscopy data, including optional processing such as ratioing and spatial mapping or imaging, is communicated to the user interface 56 for presentation to the user.

In the illustrated embodiments, the first and second sampling regions correspond to different metabolites of the same nuclear species. For example, NAA, creatine, and choline are metabolites of the same nuclear species, namely the hydrogen or proton nuclear species. More generally, the first and second sampling regions correspond to different resonant species. The localizing magnetic field gradient is determined suitable for acquiring the first resonant species magnetic resonance localized to the first sampling region. The second sampling region defined by the localizing magnetic field gradient for the second resonant species magnetic resonance is determined. The second sampling region is spatially shifted from the first sampling region due to different gyromagnetic ratios of the first and second resonant species magnetic resonances. At least the second sampling region is displayed together with an image of a subject disposed in the main magnetic field.

In some contemplated embodiments, the first resonant species is a first nuclear species and the second resonant species is a second nuclear species different from the first nuclear species. For example, the first nuclear species may be hydrogen and the second nuclear species may be fluorine. In such multi-nuclear spectroscopy embodiments, upon acceptance by the user of the second sampling region, multi-nuclear magnetic resonance spectroscopy data are acquired using the localizing magnetic field gradient. The spectroscopy data include the first and second nuclear species magnetic resonances localized to the first and second sampling regions, respectively, by the localizing magnetic field gradient.

It is to be appreciated that the methods and apparatuses disclosed herein are readily applied to more than two metabolites. For example, while FIG. 2 shows two overlays Oₘ₁, Oₘ₂ of the first and second sampling regions Rₘ₁, Rₘ₂ on the magnetic resonance image 62 of the subject, this can be readily extended to third, fourth or more overlays denoting additional sampling regions corresponding to third, fourth or more metabolites. Thus, for example, four overlays can be displayed denoting four different regions corresponding to NAA, fat, choline, and creatine. Suitable color coding or other distinguishing features can be used to indicate which overlay corresponds with which metabolite.

It is contemplated to have the regions shifts processor 68 automatically select the volume selection gradients, based upon prior data, or collecting data with multiple volume selection gradients, and making the optimal choice. For example, the regions shift processor 68 can select default gradients and then detect whether the fat sampling region overlaps the fatty region at the boundary of the skull. Of so, the regions shift processor 68 can adjust the gradients (for example, by reversing the gradient from G_{L} to G_{L}′) to shift the fat sampling region away from the fatty outer region. More generally, the region shifts processor 68 can automatically determining the selection gradient G_{L}′ for optimal placement of the second sampling region Rₘ₂′ based upon analysis of a corresponding magnetic resonance image, data from other imaging modalities, or spectral data sampling and analysis of a plurality of candidate magnetic field gradients.

The invention has been described with reference to the preferred embodiments. Obviously, modifications and alterations will occur to others upon reading and understanding the preceding detailed description. It is intended that the invention be construed as including all such modifications and alterations insofar as they come within the scope of the appended claims or the equivalents thereof.

1. A magnetic resonance method comprising:
determining a localizing magnetic field gradient suitable for acquiring a first metabolite magnetic resonance localized to a first sampling region;
determining a second sampling region defined by the localizing magnetic field gradient for a second metabolite magnetic resonance, the second sampling region being spatially shifted from the first sampling region due to different chemical shifts of the first and second metabolite magnetic resonances; and
displaying at least the second sampling region together with an image of a subject disposed in the main magnetic field.

2. The magnetic resonance method as set forth in claim 1, further including:
displaying the first sampling region together with the second sampling region and the image of the subject disposed in the main magnetic field.

3. The magnetic resonance method as set forth in claim 1, further including:
determining a third sampling region defined by the localizing magnetic field gradient for a third metabolite magnetic resonance, the third sampling region being spatially shifted from the first and second sampling regions due to different chemical shifts of the first, second, and third metabolite magnetic resonances; and
displaying the third sampling region together with the second sampling region and the image of the subject disposed in the main magnetic field.

4. The magnetic resonance method as set forth in claim 1, wherein the image of the subject is a magnetic resonance image, and the displaying includes:
displaying overlays of the first and second sampling regions on the magnetic resonance image of the subject.

5. The magnetic resonance method as set forth in claim 1, wherein the second metabolite is fat.

6. The magnetic resonance method as set forth in claim 5, further including:
conditional upon receiving an acceptance of the second sampling region, acquiring first metabolite magnetic resonance localized to the first sampling region by the localizing magnetic field gradient.

7. The magnetic resonance method as set forth in claim 5, further including:
determining a different localizing magnetic field gradient suitable for acquiring a first metabolite magnetic resonance localized to the first sampling region;
determining a different second sampling region defined by the different localizing magnetic field gradient for the second metabolite magnetic resonance; and
displaying at least the different second sampling region together with the image of the subject disposed in the main magnetic field.

8. The magnetic resonance method as set forth in claim 7, wherein the different localizing magnetic field gradient is determined responsive to the second sampling region containing a substantial amount of fatty tissue.

9. The magnetic resonance method as set forth in claim 7, wherein the determining of the different localizing magnetic field gradient includes:
reversing a direction of at least one magnetic field gradient component of the localizing magnetic field gradient.

10. The magnetic resonance method as set forth in claim 9, wherein the reversing of the direction of the at least one magnetic field gradient component is performed responsive to one of a user selection, a graphical manipulation of the second sampling region, and an automated detection of non-optimal positioning of the second sampling region.

11. The magnetic resonance method as set forth in claim 7, wherein the determining of the different localizing magnetic field gradient includes:
automatically determining the selection gradient for optimal placement of the second sampling region based upon analysis of a corresponding magnetic resonance image, data from other imaging modalities, or spectral data sampling and analysis of a plurality of candidate magnetic field gradients.

12. The magnetic resonance method as set forth in claim 1, further including:
receiving an acceptance of the second sampling region;
acquiring magnetic resonance spectroscopy data using the localizing magnetic field gradient, the acquired magnetic resonance spectroscopy data including the first and second metabolite magnetic resonances localized to the first and second sampling regions respectively, by the localizing magnetic field gradient.

13. The magnetic resonance method as set forth in claim 1, wherein the first sampling region is a slice, and the determined localizing magnetic field gradient is a one-dimensional magnetic field gradient.

14. The magnetic resonance method as set forth in claim 1, wherein the determined localizing magnetic field gradient includes at least two spatially non-parallel magnetic field gradient components.

15. The magnetic resonance method as set forth in claim 1, further including:
selecting of the first sampling region to be contained by an anatomical region of interest indicated by the image of the subject disposed in the main magnetic field.

16. The magnetic resonance method as set forth in claim 15, further including:
acquiring magnetic resonance data using the determined localizing magnetic field gradient conditional upon the second sampling region also being contained by the anatomical region of interest.

17. The magnetic resonance method as set forth in claim 1, further including:
acquiring the image of the subject disposed in the main magnetic field, the acquiring employing one of magnetic resonance imaging, ultrasound imaging, positron emission tomography (PET) imaging, single photon emission computed tomography (SPECT) imaging, and transmission computed tomography (CT) imaging.

18. A magnetic resonance apparatus comprising:
a magnetic resonance scanner for acquiring magnetic resonance, the scanner including one or more magnetic field gradient coils for superimposing one or more localizing magnetic field gradients on a main magnetic field; and
a processor configured to perform the magnetic resonance method of claim 1.

19. A magnetic resonance method comprising:
determining a localizing magnetic field gradient suitable for acquiring a first resonant species magnetic resonance localized to a first sampling region;
determining a second sampling region defined by the localizing magnetic field gradient for a second resonant species magnetic resonance, the second sampling region being spatially shifted from the first sampling region due to different gyromagnetic ratios of the first and second resonant species magnetic resonances; and
displaying at least the second sampling region together with an image of a subject disposed in the main magnetic field.

20. The magnetic resonance method as set forth in claim 19, wherein the first and second resonant species are different metabolites of the same nuclear species.

21. The magnetic resonance method as set forth in claim 19, wherein the first resonant species is a first nuclear species and the second resonant species is a second nuclear species different from the first nuclear species.

22. The magnetic resonance method as set forth in claim 21, further including:
receiving an acceptance of the second sampling region; and
acquiring multi-nuclear magnetic resonance spectroscopy data using the localizing magnetic field gradient, the spectroscopy data including the first and second nuclear species magnetic resonances localized to the first and second sampling regions, respectively, by the localizing magnetic field gradient.
